(19) United States
(12) Patent Application Publication
(10) Pub. No.: US 2008/0025084 A1
(43) Pub. Date: Jan. 31, 2008

(54) High aspect ration bitline oxides

(76) Inventors: Rustom Irani, Santa Clara, CA (US); Boaz Eitan, Ra'anana (IL); Assaf Shappir, Kiryat Ono (IL)

Correspondence Address: EMPK & Shiloh, LLP, 116 JOHN ST,, SUITE 1201, NEW YORK, NY, 10038, US

(21) Appl. No.: 11/882,787

(22) Filed: Aug. 6, 2007

Related U.S. Application Data
(63) Continuation-in-part of application No. 11/516,617, filed on Sep. 7, 2006.
(60) Provisional application No. 60/714,852, filed on Sep. 8, 2005.

(51) Int. Cl. G11C 11/34; H01L 21/336; H01L 29/792

(52) U.S. Cl. 365/184; 257/324; 438/287; 257/E21.423; 257/E29.309

(57) ABSTRACT

A non-volatile memory device includes a plurality of word line areas each separated from its neighbor by a contact area, an oxide-nitride-oxide (ONO) layer within the word line areas and at least partially within the contact areas and protective elements, generated when spacers are formed in the periphery area, to protect silicon under the ONO layer in the contact areas. A non-volatile memory device includes a plurality of word line areas each separated from its neighbor by a contact area and bitline oxides whose height:distance aspect ratio (T:D) is at least 25% greater than the maximum height:distance (Tg:Dg) ratio of gate electrodes in the CMOS periphery to ensure remnants of sidewall material between bitlines after sidewall spacer etch, thus protecting silicon in a subsequent word line salicidation step.

### CROSS-REFERENCE(S) TO RELATED APPLICATION(S)

This application is a continuation-in-part of U.S. Ser. No. 11/516,617, filed 7 Sep. 2006, which claims priority from U.S. Provisional No. 60/714,852 filed 8 Sep. 2005. The disclosures of all these applications, including all appendixes thereof, are incorporated herein by reference.

### TECHNICAL FIELD

The disclosure relates to techniques for fabricating semiconductor devices and, more particularly, to non-volatile memory (NVM) devices, such as oxide-nitride-oxide (ONO) devices, one form of which is nitride read only memory (NROM), or other microelectronic cells or structures.

### BACKGROUND

The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals.

The terminals of a field effect transistor (FET) are commonly named source, gate and drain. In the FET a small amount of voltage is applied to the gate in order to control current flowing between the source and drain. In FETs the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate, and two spaced-apart n-type diffusion areas—one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric under the gate is also commonly referred to as “gate oxide” or “gate dielectric”.) Electrical connections (not shown) may be made to the source, the drain, and the gate. The substrate may be grounded.

Generally, when there is no voltage on the gate, there is no electrical conduction (connection) between the source and the drain. As voltage (of the correct polarity) is applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

The Floating Gate Transistor

A floating gate transistor is generally a transistor structure, broadly based on the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor, the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges from the floating gate are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “1”.) That represents the programming “half” of how a floating gate memory cell operates. The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Normally, the floating gate non-volatile memory (NVM) cell has only a single “charge-storing area”—namely, the conductive floating gate (FG) structure, and can therefore only store a single bit of information (binary “1” or binary “0”). More recently, using a technology referred to as “multi-level cell” (MLC), two or more bits can be stored in and read from the floating gate cell.

The NROM Memory Cell

Another type of memory cell, called a “nitride, read only memory” (NROM) cell, has a charge-storage structure which is different from that of the floating gate memory cell and which permits charges to be stored in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around as in the example of the conductive floating gate of the floating gate memory cell. A first bit of binary information (binary “1” or binary “0”) can be stored in a first portion (such as the left-hand side) of the charge-trapping medium, and a second bit of binary information (binary “1” or binary “0”) can be stored in a second portion (such as the right-hand side) of the charge-trapping medium. An alternative viewpoint is that different charge concentrations can be considered for each bit of storage. Using MLC technology, at least two bits can be stored in and read from each of the two portions (charge storage areas) of the charge-trapping medium (for a total of 4 bits), similarly 3 bits or more than 4 bits may be identified.

FIG. 3 illustrates a basic NROM memory cell, which may be viewed as an FET with an “ONO” structure inserted between the gate and the substrate. (One might say that the ONO structure is “substituted” for the gate oxide of the FET.)

Other types of NVM cells may have ONO structures, such as SONOS (Silicon Oxide Nitride Oxide Semiconductor) and TANOS (Tantalum Nitride Oxide Semiconductor) devices, where either or both layers of oxide may include or embody silicon or alternate oxides (such as Aluminium Oxide) yet all of these are explicitly contemplated herein.

The ONO structure is a stack (or “sandwich”) of bottom (lower) oxide 322, a charge-trapping material such as nitride 324, and a top (upper) oxide 326. The ONO structure may have an overall thickness of approximately 10-25 nm, such as 18 nm, as follows:

the bottom oxide layer 322 may be from 3 to 6 nm, for example 4 nm thick;

the middle nitride layer 324 may be from 3 to 8 nm, for example 4 nm thick; and

the top oxide layer 326 may be from 5 to 15 nm, for example 10 nm thick.

The NROM memory cell has two spaced apart diffusions 314 and 316 (which can function as source and drain, as discussed hereinbelow), and a channel region 320 defined in the substrate between the two diffusion regions 314 and 316, and a gate 328 disposed above the ONO stack (322, 324, 326).

In FIG. 3, the diffusions are labeled “N+”. This means that they are regions in the substrate that have been doped with an electron donor material, such as phosphorous or arsenic. These diffusions are typically created in a larger region which is p-type cell well (CW) is doped with boron (or indium or both). This is the normal “polarity” for a NVM cell employing electron injection (but which may also employ hole injection, such as for erase). With opposite polarity (boron or indium implants in a n-type cell well), the primary injection mechanism would be for holes, which is generally accepted to be not as effective as electron injection. One skilled in the art will recognize that the concepts disclosed herein can be applied to opposite polarity devices.

The charge-trapping material 324 is non-conductive, and therefore, although electrical charges can be stored in the charge-trapping material, they are not free to move around, they will generally stay where they are stored. Nitride is a suitable charge-trapping material. Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of storing at least two bits of data—at least one bit(s) in a first storage area of the nitride layer 324 represented by the dashed circle 323, and at least one bit(s) in a second storage area of the nitride layer 324 represented by the dashed circle 321. Thus, the NROM memory cell can be considered to comprise two “half cells”, each half cell capable of storing at least one bit(s). It should be understood that a half cell is not a physically separate structure from another half cell in the same memory cell. The term “half cell”, as it may be used herein, is used herein only to refer to the “left” or “right” bit storage area of the ONO stack (nitride layer). The storage areas 321, 323 may variously be referred to as “charge storage areas”, “charge trapping areas”, and the like, throughout this document. (The two charge storage areas may also be referred to as the right and left “bits”.)

Each of the storage areas 321, 323 in the charge-trapping material 324 can exert a field effect on the channel region 320 between the source and the drain, in a manner similar to how a normal FET works, as described hereinabove (FIG. 2).

Generally, if a charge is stored in a given storage area of the charge-trapping material, this represents a binary “1”, and if no charge is stored in a given storage area of the charge-trapping material, this represents a binary “0”. (Again, these designations are arbitrary, and can be reversed to that the charged state represents binary “0” and the discharged state represents binary “1”.) That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is.

Generally, one feature of NROM cells is that rather than performing “symmetrical” programming and reading, NROM cells are beneficially programmed and read “asymmetrically”, which means that programming and reading occur in opposite directions. The arrows labeled in FIG. 3 are arranged to illustrate this point. Programming may be performed in what is termed the “forward” direction and reading may be performed in what is termed the “opposite” or “reverse” direction.

“Reading” an NROM Cell

Reading an NROM memory cell may involve applying voltages to the terminals of the memory cell comparable to those used to read a floating gate memory cell, but reading may be performed in a direction opposite to that of programming. Generally, rather than performing “symmetrical” programming and reading (as is the case with most SONOS and the floating gate memory cell, described hereinabove), the NROM memory cell is usually programmed and read “asymmetrically”, meaning that programming and reading occur in opposite directions. This is illustrated by the arrows in FIG. 3. Programming is performed in what is termed the forward direction and reading is performed in what is termed the opposite or reverse direction. For example, generally, to program the right storage area 323 (in other words, to program the right “bit”), electrons flow from left (source) to right (drain). To read the right storage area 323 (in other words, to read the right “bit”), voltages are applied to cause electrons to flow from right to left, in the opposite or reverse direction. For example, generally, to program the left storage area 321 (in other words, to program the left “bit”), electrons flow from right (source) to left (drain). To read the left storage area 321 (in other words, to read the left “bit”), voltages are applied to cause electrons to flow from left to right, in the opposite or reverse direction. See, for example, U.S. Pat. No. 6,768,165.

Memory Array Architecture, Generally

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

As discussed hereinabove, each memory cell comprises a first diffusion (functioning as source or drain), a second diffusion (functioning as drain or source) and a gate, each of which has to receive voltage in order for the cell to be operated, as discussed hereinabove. Generally, the first diffusions (usually designated “source”) of a plurality of memory cells are connected to a first bit line which may be designated “BL(n)”, and second diffusions (usually designated “drain”) of the plurality of memory cells are connected to a second bit line which may be designated “BL(n+1)”. Typically, the gates of a plurality of memory cells are connected to common word lines (WL).

The bit lines may be “buried bit line” diffusions in the substrate, and may serve as the source/drain diffusions for the memory cells. The wordlines may be polysilicon structures and may serve as the gate elements for the memory cells.

FIG. 4 illustrates an array of NROM memory cells (labeled “a” through “i”) connected to a number of word lines (WL) and bit lines (BL). For example, the memory cell “e” has its gate connected to WL(n), its source (left hand diffusion) is connected to BL(n), and its drain (right hand diffusion) is connected to BL(n+1). The nine memory cells illustrated in FIG. 4 are exemplary of many millions of memory cells that may be resident on a single chip.

Notice, for example that the gates of the memory cells “e” and “f” (to the right of “e”) are both connected to the same word line WL(n). (The gate of the memory cell “d” to the left of “e” is also connected to the same word line WL(n).) Notice also that the right hand terminal (diffusion) of memory cell “e” is connected to the same bit line BL(n+1) as the left-hand terminal (diffusion) of the neighboring memory cell “f”. In this example, the memory cells “e” and “f” have two of their three terminals connected together.

The situation of neighboring memory cells sharing the same connection—the gates of neighboring memory cells being connected to the same word line, the source (for example, right hand diffusion) of one cell being connected to the drain (for example left hand diffusion) of the neighboring cell—is even more dramatically evident in what is called “virtual ground architecture” wherein two neighboring cells actually share the same diffusion. In virtual ground array architectures, the drain of one memory cell may actually be the same diffusion which is acting as the source for its neighboring cell. Examples of virtual ground array architecture may be found in U.S. Pat. Nos. 5,650,959; 6,130,452; and 6,175,519, incorporated in their entirety by reference herein.

FIG. 4A illustrates, very generally, an exemplary overall physical layout of a NVM memory chip 450 having two distinct areas—a first “Array” area (generally designated “452”) which contains the memory cells, wordlines, and bitlines (such as schematically illustrated in FIG. 4), and a second “CMOS” area (generally designated “454”; also referred to as “peripheral” area) containing control circuits (not shown) which exercise control over the individual memory cells via the wordlines and bitlines connecting the cells. The Array area 452 may be split into two Array areas 452a and 452b, with a narrow CMOS area 454a extending vertically between the two Array areas, and connecting to wordlines horizontally traversing the Array areas. A region 454b of CMOS circuitry may be arranged horizontally across the top(s) of the Array area(s), for connecting to the top ends of the bitlines. Another region 454c of CMOS circuitry may be arranged horizontally across the bottom(s) of the Array area(s), for connecting to the bottom ends of the bitlines. Generally, the purpose of this figure is simply to show that CMOS circuitry is typically implemented on the same integrated circuit (IC) chip as the memory cells and array, and therefore, processes which affect one (such as CMOS) may affect the other (Array).

FIG. 5 illustrates, generally, a portion of a memory array 500, such as may commonly be used for NROM (nitride read only memory) arrays.

The memory array 500 comprises a plurality (three shown) of bit lines 502 extending generally parallel to one another, in “columns” of the array. The bit lines 502 may be buried bit line diffusions formed within the substrate. Note that the bit lines 502 are spaced a distance “d” from one another.

The memory array 500 further comprises a plurality (five shown) of word lines 504 extending generally parallel to one another, in “rows” of the array. The wordlines 504 are typically polysilicon lines formed on the surface of the substrate including, on underlying structures previously formed on the surface of the substrate. For example, a charge storage layer, such as an ONO layer (not shown in FIG. 5, see for example FIGS. 6A and 6B), may be formed on the surface of the substrate, and may be a continuous layer covering generally the entire array area.

Memory cells 506 may be formed between two adjacent bit lines 502, under a wordline 504, and are shown with dashed lines (including a portion of the substrate under the bit lines themselves). A given bit line 502 may server as the source (or drain) of a given memory cell and as the drain, (or source) of an adjacent memory cell, as described hereinabove—the source/drain designation depending upon the operation (such as program or read) that the memory cell is performing at a given time.

When using diffusion bit lines (as contrasted with metal bit lines), it is necessary to provide contacts to the bit lines. In a typical situation, there may be a contact at every 16 (or 32) cells along a bit line. Therefore, the wordlines 504 are grouped into sections, such as section 504a and section 504b, which are separated from one another, as illustrated, leaving an expanse of area 510 between the two sections 504a and 504b. This area 510 is referred to as the “contact area”, because that is where connections (contacts) are made to the bit lines 502. FIG. 5 shows a contact 512 for each of the bit lines 502, in the contact area 510.

Anti-punchthrough (APT) implants may be implanted in areas between two adjacent wordlines 504.

Dual Polysilicon Process

The following patents and patent applications describe a dual polysilicon process (DPP) for the NROM cell:

US 2004/0157393 to Hwang describes a manufacturing process for a non-volatile memory cell of the SONOS type which attempts to reduce or minimize the undesirable effects of small dimension components.

U.S. Pat. No. 6,686,242 B2 to Willer et al. describes an NROM cell that they claim can be implemented within a 4F2 area.

U.S. Ser. No. 11/247,733, assigned to the common assignees of the present invention, describes a further process for manufacturing NROM cells.

In the DPP process, a first polysilicon layer is deposited in columns between which the bit lines 502 are implanted. Bitline oxides (not shown in FIG. 5, see FIGS. 8A and 8B) are deposited in the spaces between first polysilicon columns and may be formed as blocked columns covering the bit lines 502. The wordlines may then be deposited as a second polysilicon layer, cutting the columns of the first polysilicon layer into islands between bit lines 502. For NROM cells, an ONO layer (not shown in FIG. 5, see FIGS. 6A and 6B) is laid down over the entire array prior to deposition of the polysilicon layers and it may be removed from above bit lines 502. The second polysilicon may be silicided to reduce the resistance of the wordlines 504.

One method of silicidation is to silicide the second polysilicon layer after its deposition, but prior to patterning of the word lines. Tungsten silicide is typically used for this purpose. The resulting silicided polysilicon is then etched to be the wordlines 504.

Self-aligned silicidation, known as “salicide”, is an alternative method for silicidation of wordlines. In this process, word lines are first patterned, after which the second polysilicon layer is etched, to generate the word lines, and oxide spacers (sidewall spacers) are then created on the array. After that has been completed, the array is silicided. The silicidation self-aligns to the second polysilicon wordlines. For the salicide process, copper silicide or nickel silicide are typically used, rather than tungsten silicide.

Note that, in the wordline areas, oxide spacers are not typically formed. Instead, the oxide for the sidewall spacers completely fills the gap between word lines.

During salicidation of the polysilicon, any exposed silicon will be salicided as well. (This holds true for any blanket process performed on the substrate. Anything which is exposed will be affected by the process.) Salicidation of exposed silicon can be a particular problem in the area of the bit line contacts. If the area between the bit lines is not protected, such with an STI (Silicon Trench Isolation) or another dielectric layer (barrier), salicidation of this layer will create a leakage path.

Additional Background Information

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arrays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer. Some examples may be found in commonly-owned U.S. Pat. Nos. 5,966,603, 6,030,871, 6,133,095 and 6,583,007.

Commonly-owned patents also disclose algorithms and methods of operation for each segment or technological application, such as: fast programming methodologies in all flash memory segments, with particular focus on the data flash segment, smart programming algorithms in the code flash and EEPROM segments, and a single device containing a combination of data flash, code flash and/or EEPROM. Some examples may be found in commonly-owned U.S. Pat. Nos. 6,954,393 and 6,967,896.

A more complete description of NROM and similar ONO cells and devices, as well as processes for their development may be found at “Non Volatile Memory Technology”, 2005 published by Saifun Semiconductor and materials presented at and through http://siliconnexus.com, both incorporated by reference herein in their entirety.

Further description of NROM and related technologies are presented in the following publications, all of which are incorporated by reference herein in their entirety:

“Design Considerations in Scaled SONOS Nonvolatile Memory Devices” presented at and through:

http://klabs.org/richcontent/MemoryContent/nvmt_symp/nvmts_{—}2000/presentations/bu_white_sonos_lehigh_univ.pdf,

“SONOS Nonvolatile Semiconductor Memories for Space and Military Applications” presented at and through:

http://klabs.org/richcontent/MemoryContent/nvmt_symp/nvmts_{—}2000/papers/adams_d.p df,

“Philips Research—Technologies—Embedded Nonvolatile Memories” presented at and through:

http://research.philips.com/technologies/ics/nvmemories/index.html, and

“Semiconductor Memory: Non-Volatile Memory (NVM)” presented at and through:

http://ece.nus.edu.sg/stfpage/elezhucx/myweb/NVM.pdf

Glossary

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
anisotropic literally, one directional. An example of an anisotropic process is sunbathing. Only surfaces of the body exposed to the sun become tanned. (see “isotropic”).
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of a NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.
bit line or bitline (BL). A conductor connected to (or which may actually be) the drain (or source) of a memory cell transistor.
byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be formed using the standard range of prefixes, e.g., kilobyte (KB), megabyte (MB) and gigabyte (GB).
cap a term used to describe layers of a material disposed over another, dissimilar material, typically to protect the underlying material from damage during subsequent processing steps. A cap may be left in place, or removed, depending upon the situation.
Cell Well (CW) the cell well is an area in the silicon substrate that is prepared for functioning as a transistor or memory cell device by doping with an electron acceptor material such as boron or indium (p, electron acceptors or holes) or with an electron donor material such as phosphorous or arsenic (n, electron donors). The depth of a cell well is defined by the depth of the dopant distribution.
CHEI short for channel hot electron injection. sometimes abbreviated “CHE”.
CHISEL short for channel initiated secondary electron.
CMOS short for complementary metal oxide semiconductor. CMOS consists of n-channel and p-channel MOS transistors. Due to very low power consumption and dissipation as well minimization of the current in “off” state CMOS is a very effective device configuration for implementation of digital functions. CMOS is a key device in state-of-the-art silicon microelectronics.
   CMOS Inverter: A pair of two complementary transistors (a p-channel and an n-channel) with the source of the n-channel transistor connected to the drain of the p-channel one and the gates connected to each other. The output (drain of the p-channel transistor) is high whenever the input (gate) is low and the other way round. The CMOS inverter is the basic building block of CMOS digital circuits.
   NMOS: n-channel CMOS.
   PMOS: p-channel CMOS.
CMP short for chemical-mechanical polishing. CMP is a process, using both chemicals and abrasives, comparable to lapping, for removing material from a built up structure, resulting in a particularly planar resulting structure.
Dopant element introduced into semiconductor to establish either p-type (acceptors) or n-type (donors) conductivity; common dopants in silicon: p-type, boron, B, Indium, In; n-type phosphorous, P, arsenic, As antimony, Sb.
EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and more typically a full Page. While an erase and rewrite of a location appears nearly instantaneous to the user, the write process is usually slightly slower than the read process; the chip can usually be read at full system speeds.
EPROM short for erasable, programmable read only memory. EPROM is a memory cell in which information (data) can be erased and replaced with new information (data).
Erase a method to erase data on a large set of bits in the array, by applying voltage scheme that inject holes or remove electrons in the bit set. This method causes all bits to reach a low Vt level.
FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.
Flash memory Flash memory is a form of non-volatile memory (EEPROM) that can be electrically erased and reprogrammed. Flash memory architecture allows multiple memory locations to be erased or written in one programming operation.
FN tunneling Field emission—also called Fowler-Nordheim tunneling—is the process whereby electrons tunnel through a barrier in the presence of a high electric field. This quantum mechanical tunneling process is an important mechanism for thin barriers as those in metal-semiconductor junctions on highly-doped semiconductors. Using FN tunneling, electrons can be moved to the floating gate of a MOSFET memory cell.
half cell this term is sometimes used to refer to the two distinct charge storage areas (left and right bits) of an NROM memory cell.
HHI short for hot hole injection
isotropic literally, identical in all directions. An example of an isotropic process is dissolving a tablet in water. All exposed surfaces of the tablet are uniformly acted upon. (see “anisotropic”)
mask a layer of material which is applied over an underlying layer of material, and patterned to have openings, so that the underlying layer can be processed where there are openings. After processing the underlying layer, the mask may be removed. Common masking materials are photoresist and nitride. Nitride is usually considered to be a “hard mask”.
MLC short for multi-level cell. In the context of a floating gate (FG) memory cell, MLC means that at least two bits of information can be stored in the memory cell. In the context of an NROM memory cell, MLC means that at least four bits of information can be stored in the memory cell—at least two bits in each of the two charge storage areas.
MOS short for metal oxide semiconductor.
MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).
nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of a NROM memory cell having an ONO layer, as a charge-trapping material.
n-type semiconductor in which concentration of electrons is higher than the concentration of “holes”. See p-type.
NROM short for nitride read only memory.
NVM short for non-volatile memory. NVM is computer memory that can retain the stored information even when not powered. Examples of non-volatile memory include read-only memory, flash memory, most types of magnetic computer storage devices (e.g. hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which make it unsuitable for use as primary storage. Typically non-volatile memory either costs more or performs worse than volatile random access memory. (By analogy, the simplest form of a NVM memory cell is a simple light switch. Indeed, such a switch can be set to one of two (binary) positions, and “memorize” that position.)
ONO short for oxide-nitride-oxide. ONO is used as a charge storage insulator consisting of a sandwich of thermally insulating oxide, and charge-trapping nitride.
oxide commonly used to refer to silicon dioxide (SiO2). Also known as silica. SiO2 is the most common insulator in semiconductor device technology, particularly in silicon MOS/CMOS where it is used as a gate dielectric (gate oxide); high quality films are obtained by thermal oxidation of silicon. Thermal SiO2 forms a smooth, low-defect interface with Si, and can be also readily deposited by CVD. Some particular applications of oxide are:
   LV Oxide short for low voltage oxide. LV refers to the process used to deposit the oxide.
   HV Oxide short for high voltage oxide. HV refers to the process used to deposit the oxide
   STI Oxide short for shallow trench oxide. Oxide-filled trenches are commonly used to separate one region (or device) of a semiconductor substrate from another region (or device).
Poly short for polycrystalline silicon (Si). Heavily doped poly Si is commonly used as a gate contact in silicon MOS and CMOS devices;
p-type semiconductor in which concentration of “holes” is higher than the concentration of electrons. See n-type. Examples of p-type silicon include silicon doped (enhanced) with boron (B), Indium (In) and the like.
Program a method to program a memory cells, or half cells, typically by applying a voltage scheme that injects electrons to increase the Vt of the cells or half cells being programmed.
PROM short for programmable read-only memory.
RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.
Read a method to read the digital data stored in a memory cell.
resist short for photoresist. also abbreviated “PR”. Photoresist is often used as a masking material in photolithographic processes to reproduce either a positive or a negative image on a structure, prior to etching (removal of material which is not masked). PR is usually washed off after having served its purpose as a masking material.
ROM short for read-only memory.
SEI short for secondary electron injection (or simply “secondary injection”). SEI occurs as a result of impact ionization by CHE electrons (e1) near the drain diffusion, generating an electron-hole pair (e2-h2), the hole (h2) of which continues into the substrate whereat another impact ionization results in another electron-hole pair (e3-h3), and the e3 electron becomes injected into the charge storage area(s) of the memory cell.
Si Silicon, a semiconductor.
SLC short for single level cell. In the context of a floating gate (FG) memory cell, SLC means that one bit of information can be stored in the memory cell. In the context of an NROM memory cell, SLC means that at least two bits of information can be stored in the memory cell.
SONOS Si-Oxide-Nitride-Oxide-Si, another way to describe ONO with the Si underneath and the Poly gate on top.
spacer a spacer, as the name implies, is a material (such as a layer of oxide) disposed on an element (such as a poly gate electrode). For example, sidewall spacers disposed on opposite sides of a gate electrode structure cause subsequent implants to occur further away from the gate than otherwise (without the spacers in place), thereby controlling a length of a channel under the gate electrode structure.
STI short for shallow trench isolation
TEHH short for Tunnel Enhanced Hot Hole injection. TEHH is an “injection mechanism”.
Units of Length Various units of length may be used herein, as follows:
   meter (m) A meter is the SI unit of length, slightly longer than a yard. 1 meter=˜39 inches. 1 kilometer (km)=1000 meters=˜0.6 miles. 10,000,000 microns=1 meter. 1,000 millimeters (mm)=1 meter. 100 centimeters (cm)=1 meter.
   micron (μm) one millionth of a meter (0.000001 meter); also referred to as a micrometer.
   mil 1/1000 or 0.001 of an inch; 1 mil=25.4 microns.
   nanometer (nm) one billionth of a meter (0.000000001 meter).
   Angstrom (Å) one tenth of a billionth of a meter. 10 Å=1 nm.
Voltage abbreviated v, or V. A voltage can be positive or negative (or zero). Usually, a negative voltage is preceeded by a minus sign (−). Sometimes a positive voltage is preceeded by a plus sign (+), or no sign at all. A number of voltages are relevant with regard to operating a memory cell, and are typically designated by the capital letter “V”, followed by another letter or letters. Some exemplary voltages of interest are are:
   KeV short for kilo (thousand) electron volts
   Vt short for threshold voltage
   Vs short for source voltage
   Vd short for drain voltage
   Vg short for gate voltage
   Vbl short for bit line voltage. (the bit line may function as source or drain)
   Vwl short for wordline voltage (which typically is the same as Vg)
word line or wordline, (WL). A conductor normally connected to the gate of a memory cell transistor. The wordline may actually be the gate electrode of the memory cell.
write a combined method of first erase a large set of bits, then program a new data into the bit set.

### BRIEF DESCRIPTION (SUMMARY)

The disclosure generally relates to establishing a geometry for an element of a semiconductor device so that in a subsequent processing step (process 1), another portion of the semiconductor device will not be adversely affected by a further subsequent processing step (process 2).

For example, and without limitation, the semiconductor device may be an NROM memory cell of a memory chip having an array area and a periphery area, the element of concern may be a bitline oxide structure in the array area, and the geometry may be the height to spacing ratio (T:D) of the bitline oxides (hereinafter referred to as “aspect ratio”), as compared with a comparable height:spacing ratio (Tg:Dg) of CMOS gate electrodes in a periphery area of the die.

Furthering this example, the subsequent processing step (process 1) may be CMOS spacer formation on sidewalls of the CMOS gate electrodes, which may involve depositing, then etching spacer material (such as oxide) which will be deposited both on the CMOS gate electrodes and the memory cell bitline oxides.

Furthering this example, the “other portion” referred to (and desired not to be adversely affected in a subsequent processing step) may be underlying silicon (and/or ONO) between bitline oxides, which can be protected from being damaged by a salicidation step (process 2) by spacer material remaining over the silicon during CMOS spacer formation (process 1). Generally, it is important to preserve/protect the integrity of the silicon and/or ONO between bitline oxides to prevent bit line-to-bit line (BL-BL) leakage which may otherwise result from silicon between the bit lines being exposed to the salicidation step (process 2). Generally, the bitlines themselves are diffusions beneath the bitline oxides—commonly referred to as “buried bitlines”.

In this example, since the bitline oxides are subjected to the same steps of depositing spacer material and etching which are used to form sidewall spacers on the CMOS gate electrodes for purposes of this disclosure, the bitline oxides and the CMOS gate electrodes may be considered to be related or corresponding structures.

Exemplary (prior art) bitline oxides of the prior art may have a height (T) of 50 nm and be spaced a distance (D) of 150 nm apart from one another, and exemplary CMOS gate electrodes may have a height (Tg) of 140 nm and be spaced a distance of (Dg) 400 nm apart from one another. Note, in this example, that T:D=50/150=1:3, Tg:Dg=140/400=1:2.85, or approximately 1:3, and that T:D (1:3) is only slightly (approximately 5%) larger than Tg:Dg.

In this example of prior art, because the aspect ratio (T:D) of the bitline oxides is only slightly greater than the aspect ratio (Tg:Dg) of the gate electrodes, there is a danger that there will not be any residual sidewall spacer material between bitline oxides which would otherwise protect silicon between the bitline oxides from damage (lowering of bitline-to-bitline resistance) during a subsequent salicidation step. For example, even if T:D is set to be 5% greater than Tg:Dg, with process variations, selected areas of the die between bitline oxides could become exposed.

According to the disclosure, generally, the bitline oxides are formed with a minimum height to spacing ratio (T:D) so that spacer material between the bit lines will not be completely etched away during CMOS spacer formation. The spacer material remaining over silicon (and/or over an ONO layer on the silicon) is referred to in the parent case as “protective element” because it protects the underlying silicon from damage in a subsequent wordline salicidation step.

Generally, T:D is set to be approximately 25% greater than Tg:Dg, to ensure that there will always be some sidewall material remaining between the bitline oxides after CMOS sidewall spacer etch, hence the underlying silicon will be protected by residual sidewall material in a subsequent salicidation step.

Hence, according to the disclosure, T:D may be at least 10% greater than Tg:Dg, including approximately 10% greater, at least 15% greater, approximately 15% greater, at least 20% greater, approximately 20% greater, at least 25% greater, and approximately 25% greater, including such numbers as approximately 30% greater, approximately 35% greater, and so forth, including very large numbers such as 200% greater (although that may not be practical, for other reasons).

Thus, the disclosure may be viewed as any of:
a method of forming bit line structures, and the bit line structures themselves, having a given geometry (height to spacing ratio, T:G);
a method of performing CMOS spacer formation in a manner that does not expose silicon between bitline oxides, and/or
a method of performing silicidation, without damaging silicon between bitline oxides.

### BRIEF DESCRIPTION OF THE DRAWING(S)

Reference will be made in detail to embodiments of the disclosure, examples of which may be illustrated in the accompanying drawing figures (FIGs). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element. It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

Throughout the descriptions set forth in this disclosure, lowercase numbers or letters may be used, instead of subscripts. For example Vg could be written V_{g}. Generally, lowercase is preferred to maintain uniform font size.) Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H20”.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4 is a diagram of a memory cell array with NROM memory cells, according to the prior art.

FIG. 4A is a diagram of an integrated circuit (IC) chip having an Array area and a CMOS area, according to the prior art.

FIG. 5 is a top view of a portion of a memory array, according to the prior art. This figure corresponds to FIG. 1 of the parent case.

FIG. 6A is a perspective view of a memory array, according to the prior art. This figure corresponds to FIG. 2A of the parent case.

FIG. 6B is a perspective view of a memory array, according to the prior art. This figure corresponds to FIG. 2B of the parent case.

FIGS. 7A and 7B are cross-sectional views of a CMOS area of a prior art memory array after deposition of a liner and its etchback, respectively, according to the prior art. These figures correspond to FIGS. 3A and 3B of the parent case.

FIGS. 8A and 8B are cross-sectional views of a contact area of the memory array of the present invention after deposition of a liner and its etchback, respectively, according to the disclosure. These figures correspond to FIGS. 4A and 4B of the parent case.

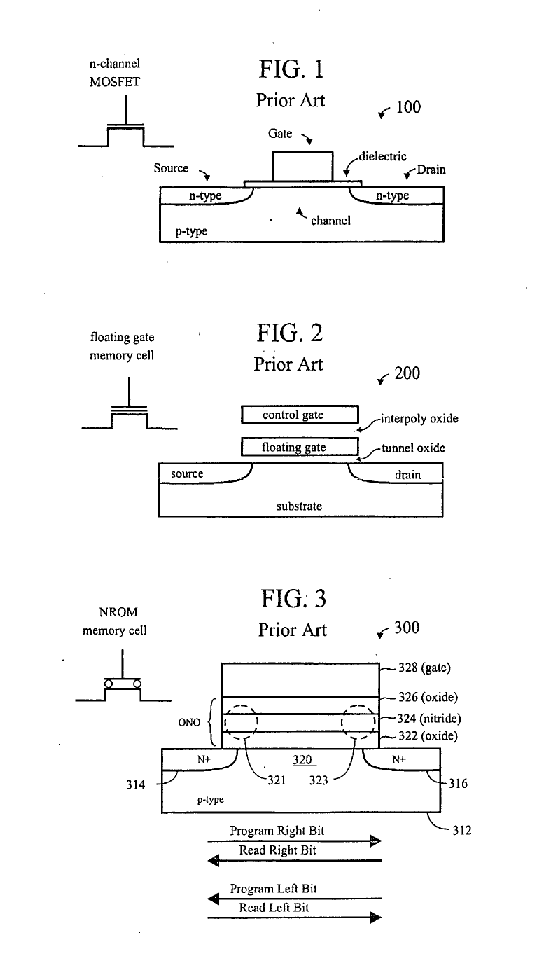

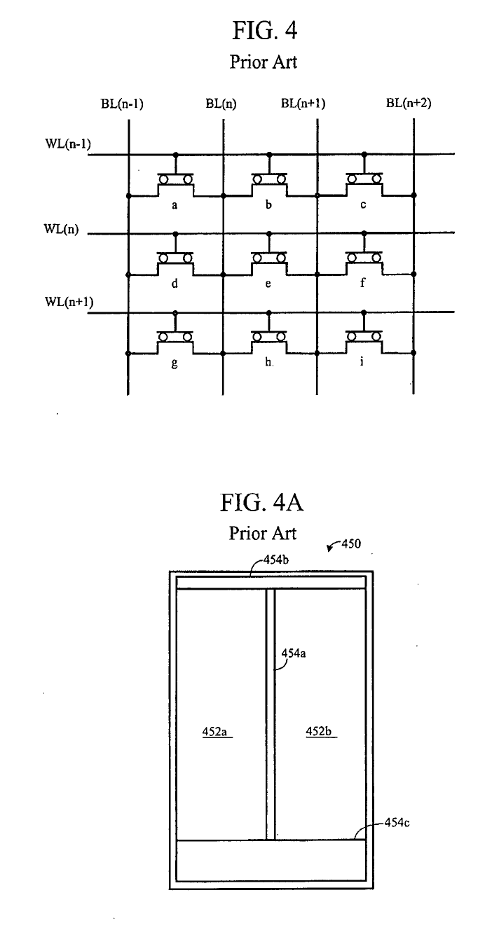

### DETAILED DESCRIPTION

This application is related to U.S. Ser. No. 11/516,617, filed 7 Sep. 2006 (which may be referred to herein as the “parent case”), which claims priority from U.S. Provisional No. 60/714,852 filed 8 Sep. 2005 (which may be referred to herein as the “provisional”).

Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon) and the like used for NVM devices.

Generally, for purposes of describing this disclosure, a memory chip comprises two areas—an array area comprising bit lines, wordlines and memory cells, and a periphery area comprising CMOS devices and circuits for operating the memory array.

In one aspect, the disclosure is generally directed to a technique for preventing silicon in the array area from becoming exposed when etching CMOS sidewall spacers in the periphery area.

In another aspect, the disclosure is generally directed to the overall silicidation (salicidation) process (for reducing wordline resistance), and by preventing silicon in the array area from becoming exposed, thereby preventing undesirable side effects of salicidation in the areas between wordlines, and bit line to bit line leakage due to salicidation.

As will become evident, these objects may be achieved by creating “high aspect ratio” bitline oxides in the memory array. Generally, a high aspect ratio bitline oxide has a height:spacing ratio (T:G) which is at least approximately 0.25 times greater than a height:spacing (Tg:Dg) of CMOS gate electrodes in a peripheral area of the chip.

This high aspect ratio for the bitline oxides may be adequate to ensure that during an etchback process such as CMOS sidewall formation, sidewall fill material between bit line oxides does not etch to silicon (or to an ONO layer on the silicon). Rather, residue (portions) of the sidewall material remain, as “protective elements” (so-called in the parent case), covering the silicon between the bitline oxides, which allows for a subsequent process, such as salicidation to be performed without undue concerns about adversely affecting the properties of underlying silicon, such as bitline-to-bitline leakage.

Therefore, as used and described herein,

sidewall formation is an example of etchback processes which in some areas of the chip are intended to etch to silicon and which in other areas of the chip it is desired that they do not etch to the silicon, and

silicidation (including salicidation) is an example of processes which can improve qualities of some structures (such as reducing wordline resistance) and which can adversely affect qualities of other features (such as bit line to bit line leakage).

For example, a non-volatile memory device, such as an NROM memory cell, includes a plurality of word line areas each separated from its neighbor by a contact area, an oxide-nitride-oxide (ONO) layer within the word line areas and at least partially within the contact areas and “protective elements” generated when spacers are formed in the periphery area, to protect silicon under the ONO layer in the contact areas.

The protective elements are remnants of the sidewall fill material that are not etched back to silicon because of the high aspect ratio of the bitline oxides.

Moreover, in accordance with an embodiment of the disclosure, the protective elements are formed of one of the following: oxide, nitride and oxide-nitride-oxide. (Spacers may be made up entirely of oxide or entirely of nitride or an oxide-nitride-oxide stack.)

According to an aspect of the disclosure, the spacers are 50-150 nm thick.

According to an aspect of the disclosure, the word line areas comprise salicided or silicided word lines. The salicided word lines may be salicided with cobalt or nickel, and the silicided word lines may be silicided with tungsten silicide.

According to an aspect of the disclosure, a non-volatile memory device comprises a plurality of word line areas each separated from its neighbor by a contact area and bitline oxides having a high aspect ratio.

According to an aspect of the disclosure, the non-volatile memory device comprises protective elements (the remnants of sidewall material) disposed at least between the bitline oxides in the contact area.

A DPP Memory Array

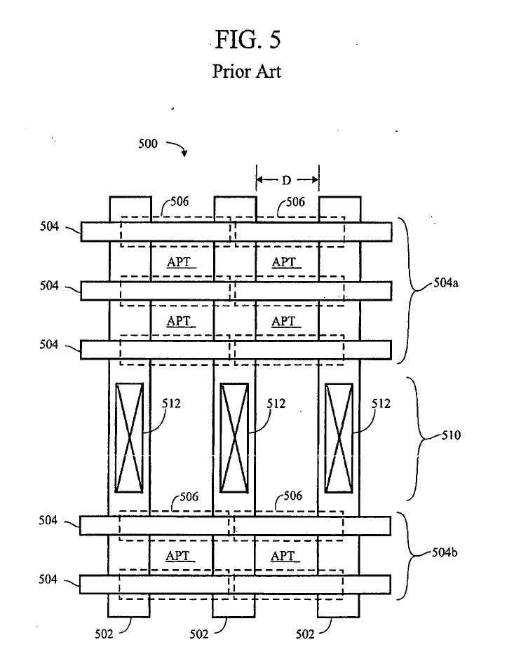

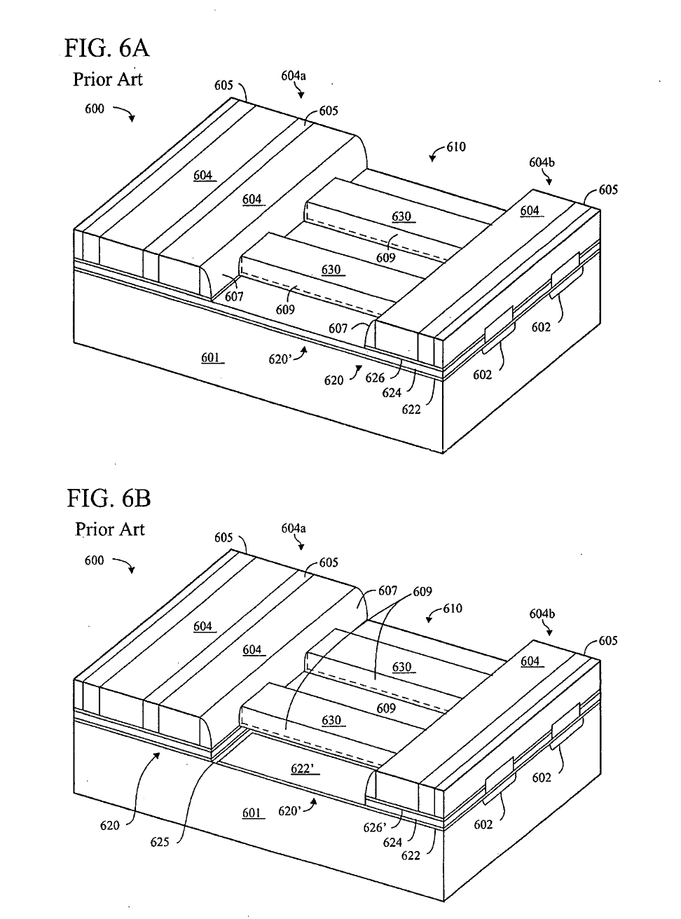

FIGS. 6A and 6B illustrate a DPP memory array 600 (compare 500), before forming contacts (not shown, see 512, FIG. 5).

Two wordlines 604 (compare 504) are shown, separated by a contact area 610 (compare 510) from another wordline 604b.

Two bit lines 602 (compare 502) are shown. The bit lines 602 are buried bit line diffusions.

A charge storage layer 620 is shown, and may be an ONO layer comprising a bottom oxide layer 622 (compare 322), a nitride layer 624 (compare 324), and a top oxide layer 626 (compare 326).

Bitline oxide structures 630 are shown. Each bitline oxide structure 630 is above a corresponding one of the bit lines 602. The structure may, or may not, incorporate the nitride layer 624 and the bottom oxide layer 622.

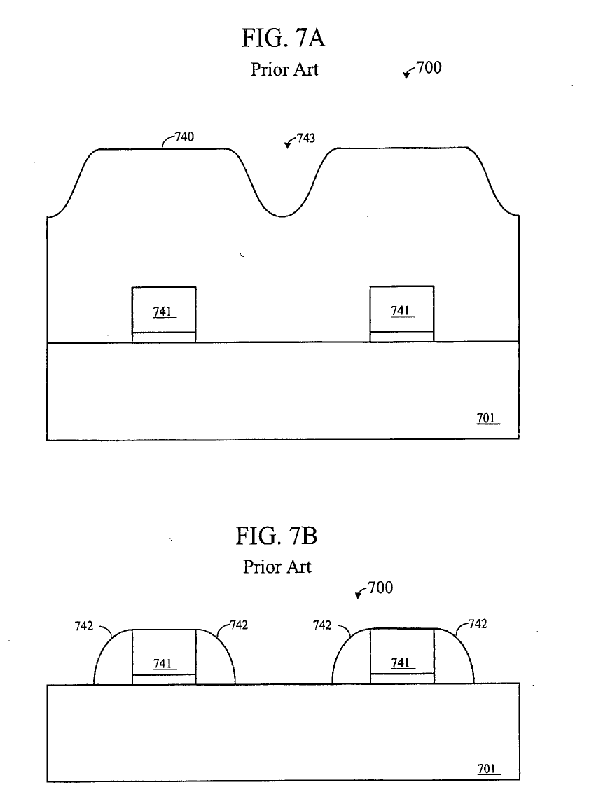

FIGS. 6A and 6B show a contact area, here labeled 610, and its neighboring word line areas 604a (compare 504a) and 604b (compare 504b). A total of three word lines 604 can be seen, lying perpendicular to and over bitline oxides 630. Oxide fill material 605 is shown between adjacent word lines 604. The oxide fill material 605 may have been deposited during an oxide spacer process (discussed hereinbelow, with respect to FIGS. 7A and 7B).

Oxide spacers 607 may be formed within the contact region 610 during the CMOS oxide spacer process, on the sides of the word lines bordering the contact region 610. And, oxide spacers 609 may also be formed within the contact region 610 on both sides of the bitline oxides 630. Generally, these spacer-like structures 607 and 609 are simply artifacts of the CMOS spacer formation, and they may protect the cell sidewall along the wordline.

Originally, an ONO layer 620, comprising a bottom oxide layer 622 (compare 322), a nitride layer 624 (compare 324) and a top oxide layer 626 (compare 326) extends across the silicon. After CMOS sidewall etch, the top oxide 626 may be consumed, resulting in only an “ON layer” 620′ (oxide 622, nitride 624) in the contact region 610. The ON layer 620′ is shown as being exposed (not covered by anything) within much of the contact region 610, notably, where it is not covered by bitline oxides 630 or oxide spacers 609 on the sidewalls of the bitline oxides 630.

The word line etch process may stop on the top oxide of the ONO layer 620 while the CMOS spacer etch process may remove the top oxide 626 and a part of the nitride layer 624.

The etching of the spacers and the word lines (1st and 2nd polysilicon layers) may etch into the ONO layer 620, which otherwise could have protected the underlying silicon.

If the ON layer 620′ is damaged, then the silicon 601 underneath the ON layer 620 in the contact region 610 may become exposed, and susceptible to salicidation.

FIG. 6B is similar to FIG. 6A, and illustrates a situation wherein the ONO layer 620 has been etched at least all the way down to the bottom oxide layer 624 in the contact area 610. And, in areas labeled 625 (referred to as ditches 35 in the parent case), all the way down to the silicon 601 at edges of the oxide spacers 607 and 609. Exposed silicon in these areas 623, may become salicided, and cause bit line to bit line leakage by forming a conductive path between adjacent bit lines 602. The modified portion of the bottom oxide 622 of the ONO layer 620′ is labeled 622′, and although it may still cover much of the contact area 610, some of the contact area 610 is exposed, at the ditches 625. The modified portion of the top oxide 626 of the ONO layer 620′ is labeled 626′.

As suggested above, the process step which produces spacers 607 and 609 may be the same step which generates spacers in the complementary metal oxide semiconductor (CMOS) periphery (not shown) of the memory array.

FIGS. 7A and 7B illustrate the generation of CMOS spacers 742 such as are typically formed on CMOS devices in a periphery (CMOS) area 700 of the overall memory chip. FIG. 7A shows two, widely spaced polysilicon gates 741, since polysilicon lines are far apart in the periphery. Generally, the gates 741 are formed on thin gate oxides, atop silicon 701.

The height (thickness) of a gate 741 including a thin gate oxide (not numbered) under the gate 741 is labeled “Tg”, and a distance between adjacent gates 741 is labeled “Dg”.

Exemplary CMOS gate electrodes 741 may have a height (Tg) of 140 nm and be spaced a distance of (Dg) 400 nm apart from one another, in which case a ratio of height:spacing Tg:Dg=140/400=1:2.85, or approximately 1:3.

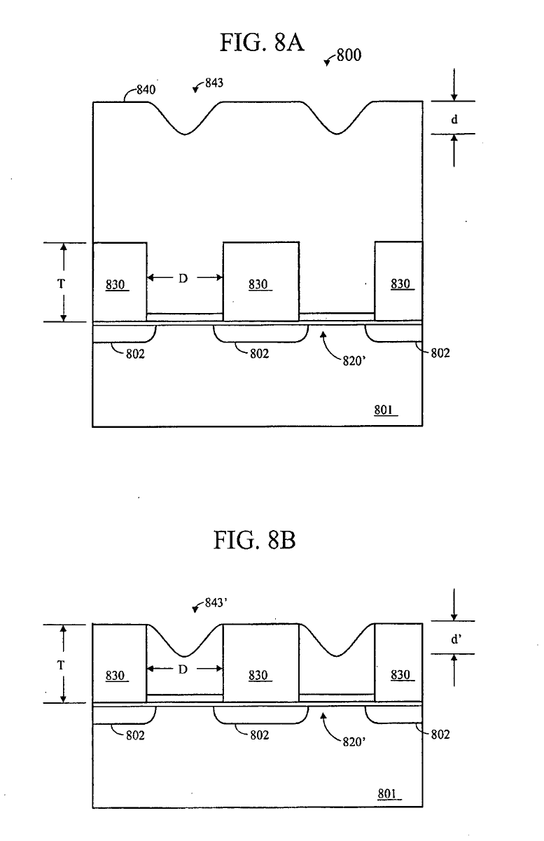

A problem arises because whereas bitline-to-bitline spacing “D” (FIG. 5, FIGS. 8A and 8B) may typically be on the order of 150 nm, a typical spacing between poly gates 741 in the periphery area may be 400 nm.

Herein lies the underlying cause of the problem being addressed by the present disclosure—namely, that during CMOS spacer formation and etching, wherein it is desired that the etch proceed all the way to silicon, spacer material which is also deposited in the array area also becomes etched, and may etch all the way to silicon, creating leakage problems as discussed above, particularly if there is a subsequent salicidation step performed. Certainly, one way to address the problem could be to mask off the array area before performing CMOS spacer etch. However, such an additional step would not be efficient. Therefore, the present disclosure provides a technique for avoiding etching to silicon in the array area during the CMOS spacer etch step, leaving CMOS spacer material in the array area, so that subsequent process steps are benign with regard to the underlying silicon.

FIG. 7A illustrates two CMOS gate electrodes 741 on a silicon substrate 701. In a first step of CMOS spacer formation, a liner material 740 is deposited, typically over the entire chip, including both the CMOS area and the Array area.

The liner material may for example be oxide or nitride or a combination of both, and is significantly thick, typically on the order of the thickness of bitline oxides 630 (FIGS. 6A and 6B) or thicker. For example, the liner material 740 may be 50-150 nm thick.

FIG. 7B illustrates that after deposition, the liner (spacer) material 740 is etched back, towards the silicon 701, resulting in generally wedge-shaped sidewall spacers 742 (thinner at the top and thicker at the bottom) on the two opposite sides of the gate electrodes 741. The width of the spacers 742 is related to the initial thickness of the liner material 740. The etch back process is typically designed to stop once the liner material 740 has been removed from on top of the polysilicon gates 741.

The CMOS liner material 740 is also deposited in the array area, over the wordlines and the bitlines, and is also etched in the array area during CMOS sidewall spacer etchback step. In the CMOS area, exposing underlying silicon during sidewall formation is not considered to be a problem. Rather, it is a desired result so that the sidewall spacers 742 are distinct, and can later perform their function of aligning source and drain diffusions away from the gate electrode 741.

According to the disclosure, the bitline oxides (830) have sufficient height (and height to spacing ratio, taking into account the aspect ratio of the CMOS gate electrodes 741) to ensure that during etching of the spacer material 740, underlying silicon is not exposed between adjacent bitline oxides (830).

Directing attention to FIGS. 6A and 6B, since the wordlines 604 of the memory array are generally close together (such as spaced 90 nm from one another), during CMOS spacer etch the etchback of spacer material between neighboring word lines does not reach down to the ONO layers 620 between word lines 604 before the etching is stopped. Rather, as shown in FIGS. 6A and 6B, the etchback leaves fill material 605 between adjacent wordlines 604.

However, in the contact area 610, there are no word lines and, as shown in FIG. 6B, the etchback of CMOS liner material may continue down to the ONO layer 620, and beyond. Structures analogous to the CMOS sidewall spacers 742 will be formed on the sides of wordlines 704 bordering the contact area 610 (see 607), as well as on the sides of bitline oxides 630 within the contact area 610. And, as discussed above, underlying silicon may become exposed, particularly right next to the structures 607 and 609 (see 625).

As discussed above, the liner (spacer) material 740 covers (is disposed over) the entire chip, which includes both the periphery (CMOS) area and the memory array (Array) area. As can be seen in FIG. 7A, which shows a portion of the CMOS periphery, the liner 740 tends to lay flat over flat elements, such as gate electrodes 741 (and, over wordlines 604, as well), and exhibits dips 743 between elements. This is normal topology for a conformal (or “blanket”) deposition (or coating)—namely, more or less following the contour of the underlying structure(s).

Generally, the closer the elements being blanket coated are to each other, the smaller the dips (743) in the coating material will be. Also, if the elements are very tall, the dips may not extend all the way down to the silicon.

As noted in the parent case, if, for example, the contact area 610 (FIGS. 6A and 6B) has elements with enough height, liner material which is etched will have very shallow dips in it. Such dips, when etched back, may not be deep enough to etch down to ONO layer 620 and hence, little or no spacer will be formed in contact area 610. This may protect silicon 601 from damage during the etchback process, as well as from subsequent processes such as salicidation.

FIGS. 8A and 8B, illustrate three adjacent bitline oxides 830 (compare 630), each having a thickness (height) “T”, and spaced a distance “D” from one another. An ONO layer 820 (compare 620) is shown on silicon 801. These bitline oxides 830 are in the contact area (610), and thus are subject to being covered by CMOS sidewall spacer material (740), and exposed to sidewall etchback. (Bitlines under wordlines, thus not in the contact area, are not subject to these processes.)

Generally, the bitlines oxides 830 are formed atop an ON layer 820′ (compare 620′) on a silicon substrate 801 (compare 701, 601). Bitline diffusions 802 (compare 602) are shown. CMOS sidewall spacer material 840 (compare 740) is shown, and dips 843 (compare 743) between adjacent bitline oxides 830.

According to the disclosure, generally, a ratio of height (T) to separation (D) for bitlines is increased (established to be at least a minimum amount) so that during a step such as CMOS sidewall etch, material such as CMOS sidewall material is not completely removed, exposing underlying silicon (and/or ONO layer(s)). In a situation where the separation (D) cannot be reduced (the denominator of the fraction is fixed), the ratio may be increased by increasing the height (T) of the bitline oxide (the numerator of the fraction is increased). Of course, if the separation (D) between bitlines can be decreased, this may serve the same objective of increasing the ratio of T:D (T divided by D).

This object may be achieved by increasing the height (thickness) of bitline oxides. For example, conventionally, bitline oxides have a thickness of approximately 50 nm.

In the prior art, such as shown in FIGS. 6A and 6B, it has been customary to defined the height of bitline oxides (630) as a function of the voltage that the oxides could handle, and they were typically 30-50 nm. Taller bitline oxides (830) may additionally be defined by the distance D between adjacent bit lines, and by the liner thickness.

For example, the height of bitline oxides 830 (FIGS. 8A and 8B) may additionally be defined as a portion, such as ¼-1, of the distance D between bit lines 10. For example, for a distance D between bit lines 10 of 120 nm, bit lines 36 may be ½ D, or 60 nm tall.

More importantly, the ratio T:D may be at least 10% greater than Tg:Dg, including approximately 10% greater, at least 15% greater, approximately 15% greater, at least 20% greater, approximately 20% greater, at least 25% greater, and approximately 25% greater, including such numbers as approximately 30% greater, approximately 35% greater, and so forth, including very large numbers such as 200% greater (although that may not be practical, for other reasons).

Generally, at least 25% (including approximately 25%) is considered to be a good number to ensure that the bitline oxides have a sufficiently high aspect ratio to ensure that there will be residual liner material between bitline oxides after CMOS sidewall etch so that silicon between the bitline oxides can be protected during subsequent wordline salicidation. Or, at least 25%. However, a ratio that is very large, such as 200% may cause keyhole formation between the wordlines and negate the desired impact. Tg:Dg ratios in periphery may range as high as 0.4 or higher (depending on the CMOS spacer width requirements), so T:D should be approximately 0.5 or higher.

According to the disclosure, bitline oxides with thickness T and spacing D between adjacent bitlines (particularly in the contact area, where they are exposed), should have a T:D ratio that is at least 25% greater than the maximum Tg:Dg ratio in the CMOS periphery (that is, the ratio of the maximum height of the CMOS gate Tg (the height of the polysilicon+gate oxide) to the minimum distance Dg between the gates sitting atop the silicon substrate).

FIG. 8B shows bitline oxides 830 such as would be in the contact area (610) after the CMOS spacer etch step, which takes place simultaneously over the array and over the periphery areas.

Since the dips 843 (compare 743) are initially relatively small and are etched slower than the flat surfaces of the sidewall material 840, the dips 843 change little or expand only slightly as they propogate downward, during the etch. (In FIG. 8B, the dips are labeled with prime, 843′.) Thus, as shown in FIG. 8A, starting with a depth of (d), the dips will end up with a depth (d′)substantially equal to, or only slightly greater than d.

As characterized in the parent case, generally, as long as the dips 843 begin with a depth (d) substantially smaller (≦90% of T) than the height (T) of the bitline oxides 830, the CMOS spacer etch step will not etch them down to ONO layer 28B, leaving a layer of protection 46 over ONO layer 28B. Generally, the amount of spacer material on top of the bitline oxide and on top of the CMOS poly gates is the same (a result of the same process step). Hence the etchback of these will also be similar. The 90% number is selected because typically there is a 10% overetch of the spacer oxide. This does not hurt the CMOS poly gate since the oxide etch has a good selectivity to silicon. However, there is no such advantage for the bitline oxide.

Typically, the thickness of the spacer material (referred to in the parent case as “liner”) is determined by the standard processes of the CMOS periphery. According to the present disclosure, the ratio of the height (T) of the bitline oxides to the distance D between bit lines depends on the liner thickness and on any process steps that may partially liner material between the bitline oxides.

It should be understood that the technique(s) described hereinabove is not limited to implementation with the salicide process. Protecting silicon in the contact area is important irrespective of the cause of the damage. Thus, increasing the height of the bit lines may be useful as a general protection for the silicon in contact areas.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. A memory cell comprising:
a charge storage layer disposed on a chip substrate;
buried bitline diffusions disposed in the substrate;
bitline oxides disposed atop the buried bitline diffusions;
wherein the bitline oxides have a height (T) and are spaced a distance (D) from one another;
wherein gate electrodes have a height (Tg) and are spaced a distance (Dg) from one another; and
wherein a ratio of T:D is at least 25% greater than a ratio of Tg:Dg.

2. The memory cell of claim 1, wherein:
the ratio Tg:Dg is based on a maximum thickness for the gate electrodes.

3. The memory cell of claim 1, wherein:
the ratio Tg:Dg is based on a minimum distance separating the gate electrodes.

4. The memory cell of claim 1, wherein:
the memory cell is a non-volatile memory (NVM) cell.

5. The memory cell of claim 1, wherein the charge storage layer comprises:
a bottom layer of oxide;
a layer of nitride disposed over the bottom layer of oxide; and
a top layer of oxide disposed over the layer of nitride.

6. A memory device comprising:
an array area comprising non-volatile memory (NVM) cells;
a CMOS area peripheral to the array area and comprising logic and control circuits; and
bitline oxides disposed in the array area;
wherein:
the bitline oxides have a high aspect ratio (T:D) of thickness to separation between bitline oxides.

7. The memory device of claim 6, wherein:
the CMOS area includes structures having an aspect ratio (Tg:Dg) of thickness to separation between CMOS structures; and
the high aspect ratio (T:D) is selected from the group consisting of at least 10% greater than Tg:Dg, approximately 10% greater than Tg:Dg, at least 15% greater than Tg:Dg, approximately 15% greater than Tg:Dg, at least 20% greater than Tg:Dg, approximately 20% greater than Tg:Dg, at least 25% greater than Tg:Dg, approximately 25% greater, approximately 30% greater than Tg:Dg, and approximately 35% greater than Tg:Dg.

8. A method of forming sidewall spacers in a memory device, comprising:
forming gate electrodes in a CMOS area of the memory device:
forming bitline oxides in an array area of the memory device;
depositing spacer material over the gate electrodes and the bitline oxides;
etching the spacer material to form sidewall spacers on sides of the gate electrodes;
wherein the bitline oxides have sufficient height to ensure that during etching of the spacer material, underlying silicon is not exposed between adjacent bitline oxides.

9. The method of claim 8, wherein:
the bitline oxides have a high aspect ratio (T:D) of thickness to separation between bitline oxides; and
the high aspect ratio (T:D) is at least at least 25% greater than a ratio of height to distance between gate electrodes (Tg:Dg).

10. A method of saliciding wordlines in a memory device, comprising:
prior to saliciding the wordlines, forming bitline oxides having sufficient height so that during sidewall spacer formation, which is also performed prior to saliciding the wordlines, silicon between adjacent bitline oxides does not become exposed, hence salicided.

11. A non-volatile memory device comprising:
a plurality of word line areas each separated from its neighbor by a contact area;
an oxide-nitride-oxide (ONO) layer within said word line areas and at least partially within said contact areas; and
protective elements, generated when spacers are formed in the periphery area, to protect silicon under said ONO layer in said contact areas.

12. The device according to claim 11 and wherein said protective elements are formed of one of the following: oxide, nitride and oxide-nitride-oxide.

13. The device according to claim 11 and wherein said spacers are formed of liners of 50-150 nm thick.

14. The device according to claim 11 and wherein said word line areas comprise salicided word lines.

15. The device according to claim 11 and wherein said word line areas comprise silicided word lines.

16. The device according to claim 14 and wherein said word lines are salicided with cobalt.

17. The device according to claim 14 and wherein said word lines are Salicided with Nickel.

18. The device according to claim 15 and wherein said word lines comprise tungsten.

19. A non-volatile memory device comprising:
a plurality of word line areas each separated from its neighbor by a contact area; and
bitline oxides whose height:distance ratio Tg:Dg is at least 25% greater than a maximum height:distance ratio Tg:Dg for elements having sidewalls in a CMOS periphery.

20. The device according to claim 29, further comprising protective elements at least between said bitline oxides in said contact area.

21. The device according to claim 20 and wherein said protective elements are formed of one of the following: oxide, nitride and oxide-nitride-oxide.

22. The device according to claim 21 and wherein said word line areas comprise salicided word lines.

23. The device according to claim 21 and wherein said word line areas comprise silicided word lines.

24. The device according to claim 22 and wherein said word lines are Salicided with cobalt.

25. The device according to claim 22 and wherein said word lines are Salicided with Nickel.

26. The device according to claim 21 and wherein said word lines are of Tungsten.
